(19) United States
(12) Patent Application Publication
(10) Pub. No.: US 2024/0392463 A1
(43) Pub. Date: Nov. 28, 2024

(54) SEMICONDUCTOR ELECTROCHEMICAL PLATING APPARATUS AND METHOD

(71) Applicant: Taiwan Semiconductor Manufacturing Company, Ltd., Hsinchu (TW)

(72) Inventors: Jun-Nan Nian, Hsinchu (TW); Jung-Chih Tsao, Hsinchu (TW); Jian-Shin Tsai, Tainan (TW); Yao-Hsiang Liang, Hsinchu (TW); Ming-Ching Chung, Tainan (TW)

(21) Appl. No.: 18/200,939

(22) Filed: May 23, 2023

(51) Int. Cl. C25D 21/04; B01D 19/00; C25D 17/00; C25D 17/06; C25D 21/12; H01L 21/288

(52) U.S. Cl. CPC C25D 21/04; B01D 19/0078; C25D 17/001; C25D 17/06; C25D 21/12; H01L 21/2885

(57) ABSTRACT

A semiconductor electrochemical plating (ECP) tool includes: a plating cell which receives an ECP solution therein; a support onto which a semiconductor substrate is selectively secured, the support being controllable to selectively dip the semiconductor substrate into ECP solution contained in the plating cell; a recirculation system including a reservoir that receives an overflow of ECP solution from the plating cell, the ECP solution being recirculated from the reservoir back to the plating cell; a bubble monitoring system that detects gas bubbles within the ECP solution; and a degassing system that inhibits at least one of gas bubble formation, nucleation and growth within the ECP solution, wherein the degassing system is controlled at least in part based upon gas bubble detection by the bubble monitoring system.

### BACKGROUND

The following relates to the semiconductor arts, and in particular, to a semiconductor electrochemical plating (ECP) apparatus and/or method.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features as shown in the accompany figures may be arbitrarily increased or reduced for clarity of discussion.

FIG. 1 is diagrammatic illustration showing a semiconductor device at various stages of a single damascene fabrication process in accordance with some embodiments disclosed herein.

FIG. 2 is diagrammatic illustration showing a semiconductor device at various stages of a dual damascene fabrication process in accordance with some embodiments disclosed herein.

FIG. 3 is a diagrammatic illustration showing an electrochemical plating (ECP) apparatus and/or tool in accordance with some embodiments disclosed herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. Further, it is to be understood that when an element is referred to as being “connected to” or “coupled to” another element, it may be directly connected to or coupled to the other element, or one or more intervening elements may be present. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “left,” “right,” “side,” “back,” “rear,” “behind,” “front,” “beneath,” “below,” “lower,” “above,” “over,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “about” may include any numerical value that can vary without changing the basic function of that value. When used with a range, “about” also discloses the range defined by the absolute values of the two endpoints, for example, “about 2 to about 4” also discloses the range “from 2 to 4.” The term “about” may refer to plus or minus 10% of the indicated number.

In accordance with some suitable embodiments, there is disclosed herein a semiconductor electrochemical plating (ECP) apparatus and/or method. In general, the fabrication and/or manufacturing of semiconductor devices is a multi-step process with various process steps being carried out using various semiconductor processing tools suitably equipped and/or provisioned for executing respective steps of the fabrication process. In practice, the manufacture of semiconductor devices may include the formation of electrical conductors (i.e., conductive vias and/or conductive lines) on semiconductor substrates and/or wafers. For example, electrically conductive leads on the semiconductor substrate or wafer can be formed by ECP or otherwise depositing an electrically conductive material such as copper (Cu) on the semiconductor substrate or wafer and into patterned trenches and/or vias. In general, ECP involves making electrical contact with the semiconductor substrate or wafer surface upon which the electrically conductive layer is to be deposited. A current may then passed through an ECP solution (i.e., a solution containing ions of the element being deposited, for example, a solution containing Cu* or the like) between an anode and the semiconductor substrate or wafer plating surface. Suitably, during the ECP process, the semiconductor substrate or wafer plating surface acts as a cathode. In practice, the electrical current causes an electrochemical reaction on the semiconductor substrate or wafer plating surface acting as a cathode, thereby resulting in the deposition of the electrically conductive layer and/or material.

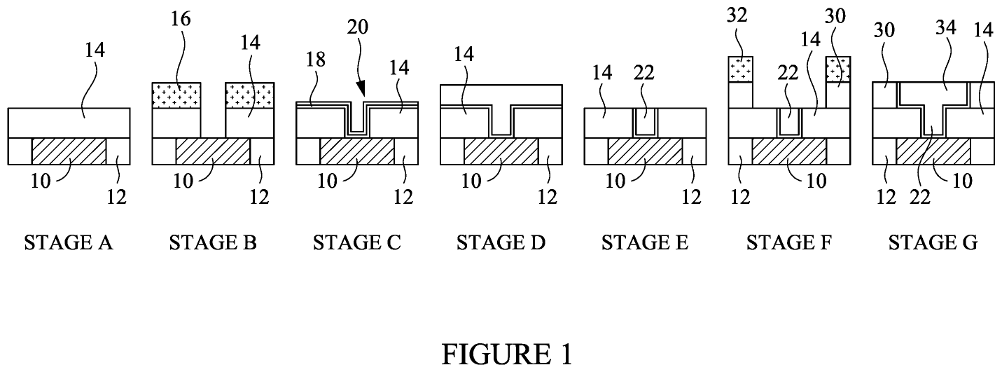

In some suitable embodiments, for example as shown in FIG. 1, the semiconductor substrate and/or wafer may be prepared and/or processed with a so-called single damascene process including multiple steps and/or stages. FIG. 1 shows a semiconductor device at various stages of a multi-step single damascene process. As shown in FIG. 1, seven stages (labeled A-G) are shown progressively from left to right.

At an initial stage A as shown in FIG. 1, the semiconductor device may include a metal or other conductor 10 (for example, a Cu or other suitable metal conductor) within a semiconductor layer 12 or the like that is overlayed with an interlayer dielectric (ILD) 14 (for example, a low-k dielectric) or the like. At stage B of FIG. 1, a suitable mask 16 is shown patterned over the ILD 14 and a via opening defined by the mask 16 is shown formed in the ILD 14 over and/or otherwise aligned with the location of the conductor 10. In some suitable embodiments, the via opening may be formed by a suitable etch or other like and/or suitable material removal process that is restricted to and/or otherwise contained within the designated location defined by the mask 16. For example, the mask 16 may be patterned and/or formed using a suitable photolithography technique or the like.

At stage C of FIG. 1, the semiconductor device is shown with the mask 16 removed and with suitable barrier and seed layers 18 and 20, respectively, having been deposited and/or otherwise formed over the ILD 14 and within the previously formed via opening. In some suitable embodiments, the barrier layer 18 may include one or more thin layers of material deposited, for example, using physical vapor deposition (PVD) or another like and/or suitable material deposition process. In some suitable embodiments, the barrier layer 18 may be formed of tantalum (Ta), tantalum nitride (TaN) or other like and/or suitable materials. In some suitable embodiments, Ta may be used as a liner and TaN may be used for the barrier. In some suitable embodiments, the barrier layer 18 is coated over with and/or by the seed layer 20, for example, via PVD or another like and/or suitable material deposition process. For example, the seed layer 20 may be formed from Cu or another metal or alloy and/or other suitable seed material(s).

As shown in stage D of FIG. 1, an ECP process may be performed to cover the seed layer 20 and/or fill the via opening, for example, with a suitable ECP material, such as Cu or another like and/or suitable ECP material. As shown in stage E of FIG. 1, chemical mechanical planarization (CMP) or another like and/or suitable material removal process may be used to remove the overfill and/or overburden deposited above and/or outside of the via opening, thereby forming and/or establishing the electrically conductive via 22 within the via opening.

In stage F of FIG. 1, a further ILD 30 (for example, a low-k dielectric) or the like is shown formed over the ILD 14. In accordance with some suitable embodiments, a further mask 32 is shown patterned over the ILD 30 and a trench opening defined by the mask 32 is shown formed in the ILD 30 over and/or otherwise aligned with the location of the via 22. In some suitable embodiments, the trench opening may be formed by a suitable etch or other like and/or suitable material removal process that is restricted to and/or otherwise contained within the designated location by the mask 32. In some suitable embodiments, the further mask 32 may be patterned and/or formed using a suitable photolithography technique and/or the like. In some suitable embodiments, the etch forming the trench opening is a selective etch suitable for removing material from the ILD 30, without removing material from the ILD 14.

At stage G of FIG. 1, the semiconductor device is shown with the mask 32 removed and with further suitable barrier and seed layers, respectively, having been deposited and/or otherwise formed over the ILD 30 and within the previously formed trench opening. Suitably, a further ECP process may be performed to cover the seed layer and/or fill the trench opening, for example, with a suitable ECP material, such as Cu or another like and/or suitable ECP material. As shown in stage G of FIG. 1, further CMP or another like and/or suitable material removal process may be used to remove the overfill and/or overburden deposited above and/or outside of the trench opening, thereby forming and/or establishing an electrically conductive line 34 within the trench opening.

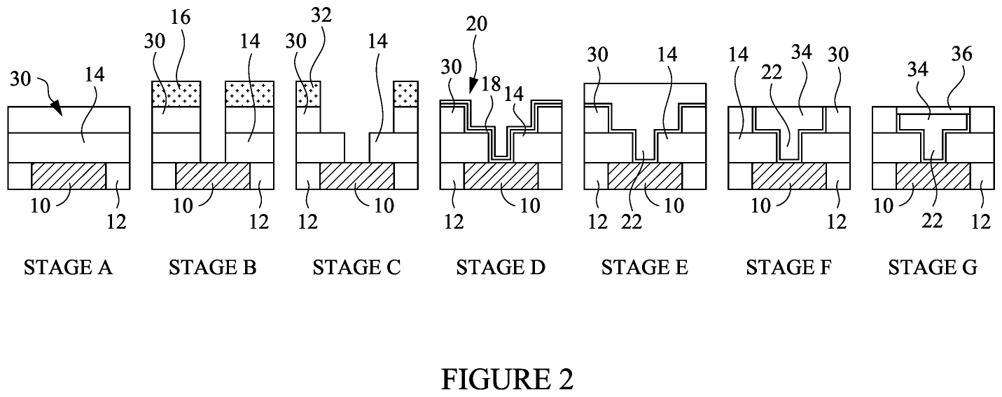

In some suitable embodiments, for example as shown in FIG. 2, the semiconductor substrate and/or wafer may be prepared and/or processed with a so-called dual damascene process including multiple steps and/or stages. FIG. 2 shows a semiconductor device at various stages of a multi-step dual damascene process. As shown in FIG. 2, seven stages (labeled A-G) are shown progressively from left to right.

At an initial stage A as shown in FIG. 2, the semiconductor device may include the metal or other conductor 10 (for example, a Cu or other suitable metal conductor) within the semiconductor layer 12 or the like that is overlayed with both the interlayer dielectric (ILD) 14 (for example, a low-k dielectric) or the like and the further ILD 30 (for example, a low-k dielectric) or the like. At stage B of FIG. 2, the first mask 16 is shown patterned over the ILD 30 and the via opening defined by the mask 16 is shown formed through the ILD 30 and into the ILD 14, for example, so as to be over and/or otherwise aligned with the location of the conductor 10. In some suitable embodiments, the via opening may be formed by a suitable etch or other like and/or suitable material removal process that is restricted to and/or otherwise contained within the designated location defined by the mask 16. In some suitable embodiments, this etch removes material from both the ILD 30 and the ILD 14. In some suitable embodiments, a first etch may be employed to remove material from the ILD 30 and a second etch may be employed to remove material from the ILD 14. Suitably, the mask 16 may be patterned and/or formed using a suitable photolithography technique and/or the like.

At stage C of FIG. 2, the semiconductor device is shown with the first mask 16 removed and with the further mask 32 patterned over the ILD 30. Suitably, the mask 32 may be patterned and/or formed using a suitable photolithography technique and/or the like. As shown, a trench opening defined by the mask 32 is shown formed in the ILD 30 over and/or otherwise aligned with the location of the via opening. In some suitable embodiments, the trench opening may be formed by a suitable etch or other like and/or suitable material removal process that is restricted to and/or otherwise contained within the designated location by the mask 32. In some suitable embodiments, the trench forming etch may be a selective etch which removes material from the ILD 30, without removing material from the ILD 14.

At stage D of FIG. 2, suitable barrier and seed layers 18 and 20, respectively, are shown having been deposited and/or otherwise formed over the ILD 30 and within the previously formed trench and via openings. In some suitable embodiments, the barrier layer 18 may include one or more thin layers of material deposited, for example, using physical vapor deposition (PVD) or another like and/or suitable material deposition process. In some suitable embodiments, the barrier layer 18 may be formed of tantalum (Ta), tantalum nitride (TaN) or other like and/or suitable materials. In some suitable embodiments, Ta may be used as a liner and TaN may be used for the barrier. In some suitable embodiments, the barrier layer 18 is coated over with and/or by the seed layer 20, for example, via PVD or another like and/or suitable material deposition process. For example, the seed layer 20 may be formed from Cu or another metal or alloy and/or other suitable seed material(s).

As shown in stage E of FIG. 2, an ECP process may be performed to cover the seed layer 20 and/or fill the trench and via openings, for example, with a suitable ECP material, such as Cu or another like and/or suitable ECP material. In this way, the electrically conductive via 22 is formed and/or established within the via opening and the trench opening is simultaneously filled. As shown in stage F of FIG. 2, chemical mechanical planarization (CMP) or another like and/or suitable material removal process may be used to remove the overfill and/or overburden deposited above and/or outside of the trench opening, thereby forming and/or establishing the electrically conductive line 34 within the trench opening. As shown at stage G of FIG. 2, a capping layer 36 may be deposited and/or formed over the electrically conductive line 34.

Notably, in the single damascene process shown in FIG. 1, the electrically conductive lines, for example, in the trench openings and the electrically conductive vias, for example, in the via openings are generally deposited and/or otherwise formed with and/or in separate distinct ECP steps and/or processes. In contrast, the electrically conductive lines and electrically conductive via can be deposited and/or formed simultaneously during the same ECP step in the dual damascene process shown in FIG. 2. Advantageously, in this way, the dual damascene process can potentially be a less expensive, a less time consuming and/or a more efficient approach, for example, as compared to the single damascene process.

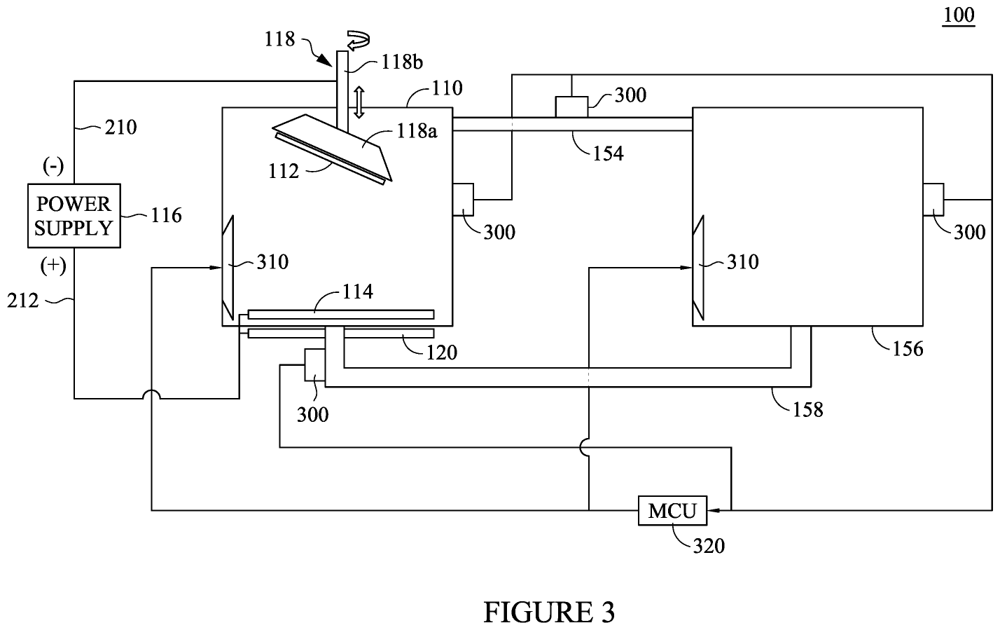

With reference now to FIG. 3, in accordance with some suitable embodiments disclosed herein, there is shown a diagrammatic illustration of an ECP apparatus and/or tool 100 provisioned and/or equipped for conducting a semiconductor ECP process. For example, the ECP apparatus and/or tool may be used in stage D of FIG. 1 or stage E of FIG. 2. In the illustrated embodiments, the ECP apparatus and/or tool includes a process vessel or tank 110 (also referred to as an electroplating cell) in which the ECP is performed. In some suitable embodiments, the process vessel or tank 10 may hold a suitable plating bath. A semiconductor substrate or wafer 112 acts as a cathode onto which material is deposited derived from an anode 114 (for example, Cu), which is disposed within the process vessel or tank 110. In some cases, a third electrode 120 is disposed beneath the vessel 110 but in proximity to the plating bath. Suitably, a power supply 116 is coupled in an open circuit with electrode 120 and a fixture 118 so as to apply a static electric charge to the semiconductor substrate or wafer 112. In some suitable embodiments, the fixture 18 is configured to hold and rotate the semiconductor substrate or wafer 112.

As shown, the fixture 118 of the ECP apparatus 100 includes a substrate holder 118a which is mounted on a rotatable spindle 118b which allows rotation of the substrate holder 118a. In some suitable embodiments, before the electrochemical plating process starts, the semiconductor substrate or wafer 112 is mounted and/or otherwise secured to the substrate holder 118a. The substrate holder 118a and the substrate or wafer 112 are then placed into the electroplating cell 110 that serves as a container and/or vessel for containing a plating solution, for example, a copper sulfate (CuSO₄) solution. In practice, the fixture 118 may be selectively lowered and raised into the electroplating cell 110 which is prefilled with the plating solution. In some suitable embodiments, the substrate holder 118b may be selectively tilted and/or angled relative to the spindle 118b, for example, so that when lowering the substrate or wafer 112 into the plating solution, the substrate or wafer 112 enters the plating solution at an angle or tilted relative to a surface of the plating solution. In accordance with some suitable embodiments, the plating solution is continually provided to the electroplating cell 110 by a pump. Suitably, the plating solution may flow upwards towards the substrate or wafer 112, then radially outward and across the substrate or wafer 112.

In some suitable embodiments, the plating solution overflows from the electroplating cell 110 to an overflow reservoir 156, for example, via one or more overflow tubes or pipes. One such overflow tube or pipe is indicated by reference number 154. Suitably, the plating solution is then filtered and returned, for example, via a suitable pump through a recirculation pipe or tube 158 to the electroplating cell 110, thus completing a recirculation of the plating solution.

In accordance with some suitable embodiments, the plating solution may include a mixture of copper salt, acid, water and various organic and inorganic additives that improve the properties of the deposited copper. Suitable copper salts for the plating solution include copper sulfate, copper cyanide, copper sulfamate, copper chloride, copper formate, copper fluoride, copper nitrate, copper oxide, copper fluorine-borate, copper trifluoroacetate, copper pyrophosphate and copper methane sulfonate, or hydrates of any of the foregoing compounds. In practice, the concentration of the copper salt used in the plating solution can vary depending on the particular copper salt used.

In some suitable embodiments, various acids may be used in the plating solution, including: sulfuric acid, methanesulfonic acid, fluoroboric acid, hydrochloric acid, hydroiodic acid, nitric acid, phosphoric acid and other suitable acids. In practice, the concentration of the acid used may vary depending on the particular acid used in the plating solution.

Additives for the copper plating solution may include brighteners, suppressors and levelers. For example, brighteners may be organic molecules that improve the specularity (or reflectivity) of the copper deposit by reducing both surface roughness and grain-size variation. Suitable brighteners include, for example, organic sulfide compounds, such as bis-(sodium sulfopropyl)-disulfide, 3-mercapto-1-propanesulfonic acid sodium salt, N-dimethyl-dithiocarbamyl propylsulfonic acid sodium salt and 3-S-isothiuronium propyl sulfonate, or mixtures of any of the foregoing compounds. For example, suppressors may be macromolecule deposition inhibitors that adsorb over the surface of the substrate and reduce local deposition rates, thereby increasing the deposition uniformity. For example, levelers may include ingredients with nitrogen functional groups and may be added to the plating solution at a relatively low concentration. In practice, leveling involves the diffusion or migration of strongly current suppressing species to corners or edges of macroscopic objects which otherwise plate more rapidly than desired due to electric field and solution mass transfer effects. The levelers may be selected from the following agents: a polyether surfactant, a non-ionic surfactant, a cationic surfactant, an anionic surfactant, a block copolymer surfactant, a polyethylene glycol surfactant, polyacrylic acid, a polyamine, aminocarboxylic acid, hydrocarboxylic acid, citric acid, entprol, edetic acid, tartaric acid, a quaternized polyamine, a polyacrylamide, a cross-linked polyamide, a phenazine azo-dye, an alkoxylated amine surfactant, polymer pyridine derivatives, polyethyleneimine, polyethyleneimine ethanol, a polymer of imidazoline and epichlorohydrine, and benzylated polyamine polymer.

Suitably, the substrate or wafer 112 (for example, acting as the cathode) and the anode 114 are both immersed in the plating solution (for example, CuSO₄ solution) containing one or more dissolved metal salts as well as other ions that permit the flow of electricity. In practice, the substrate or wafer 112 may act as a cathode onto which material from the anode 114 is deposited. In the illustrated embodiment, a DC power supply 116 has a negative output lead 210 electrically connected to the substrate or wafer 112 through one or more slip rings, brushes and/or contacts (not shown). The positive output lead 212 of the power supply 116 may be electrically connected and/or coupled to the anode 114. During use, the power supply 116 biases the substrate or wafer 112 to have a negative potential relative to the anode 114 causing an electrical current to flow from the anode 114 to the substrate or wafer 112. As used herein, electrical current flows in the same direction as the net positive ion flux and opposite the net electron flux. In practice, this causes an electrochemical reaction (for example, Cu²⁺+2e⁻=Cu) on the substrate or wafer 112 which results in the deposition of the electrically conductive layer (for example, copper) on the substrate or wafer 112. In some suitable embodiments, the ion concentration of the plating solution is replenished during the plating cycle by dissolving the anode 114 which is made of a metallic compound (for example, Cu=Cu²⁺+2e⁻).

In some suitable embodiments, a processing system is used with the ECP apparatus 100 to bring the substrate or wafer 112 into contact with the plating solution. In some suitable embodiments, the electroplating cell 110 holds the plating solution, and the substrate or wafer 112 is immersed into the plating solution. As such, suitably, the electroplating cell 110 is sized based at least in part upon the size of the substrate or wafer 112 that is being processed.

In practice, circulation of the plating solution mixes the plating solution and aids in the replenishment of the plating solution adjacent to the surface of the substrate or wafer 112. In order to maintain circulation within the electroplating cell 110, the ECP apparatus 100 may additionally include the overflow reservoir 156. The overflow reservoir 156 is arranged to receive the plating solution after the plating solution has entered the electroplating cell 110 (for example, through an entry port at the bottom of the electroplating cell 110) and has circulated through the electroplating cell 110 before entering the overflow reservoir 156. As such, the overflow reservoir 156 may receive plating solution from one or more overflow pipes or tubes 154 in fluid communication with the electroplating cell 110 at or near a top of the electroplating cell 110 so that plating solution can enter the bottom of the electroplating cell 110, circulate around the electroplating cell 110, and make its way up through the electroplating cell 110 before flowing toward a top of the electroplating cell 110 and entering the overflow reservoir 156, for example, via one or more overflow pipes or tubes 154.

As shown, the overflow reservoir 156 may be connected and/or operatively couple to the recirculation line 158. Suitably, the recirculation line 158 receives the plating solution from the overflow reservoir 156 and recirculates the plating solution from the overflow reservoir 156 back to the electroplating cell 110. In some suitable embodiments, the recirculation line 158 may include a pump that is utilized to pump the plating solution back into the electroplating cell 110 through, for example, the entry port. In practice, the pump may also aid in the mixing of the plating solution within the electroplating cell 110.

In some suitable embodiments, the recirculation line 158 may also include a filter. For example, the filter may help to remove particulates and other impurities from the plating solution as the plating solution is recirculated. These impurities may include silicate, aggregated surfactant, oil drop by-products of the plating solution, and other particles that may form during the processing reactions or else otherwise be in the plating solution. In practice, the filter size may be dependent at least on the size of the silicates, aggregated surfactant, and the oil drop by-product impurities.

In some suitable embodiments, the recirculation line 158, pump, and filter cooperate to provide a desired recirculation rate of the plating solution to the electroplating cell 110. In some embodiments, this recirculation rate may be used to ensure that the plating solution is properly mixed so that concentration variations (for example, that result from the chemical reactions) at different points within the plating solution are kept at a minimum.

In some suitable embodiments, for example as shown in FIG. 3, the ECP apparatus and/or tool 100 includes a degassing mechanism and/or system for mitigating against and/or inhibiting bubble formation, nucleation and/or growth within the plating solution during an ECP process carried out with the ECP apparatus 100. Advantageously, such mitigation in the manner disclosed herein can reduce defects that are potentially caused by bubbles and improve manufacturing yield, for example by improving the yield of the electroplating steps illustrated in FIG. 1 and FIG. 2.

As shown in the illustrated embodiment, the degassing mechanism and/or system may include one or more bubble sensors 300, one or more acoustic wave generators 310 and a microprocessor or controller 320. In some suitable embodiments, generally, the bubble sensors 300 monitor, sense, measure and/or otherwise detect gas bubbles within the plating solution, for example, at one or more locations where the bubble sensors 300 are positioned and/or arranged. For example, in suitable embodiments, as shown in FIG. 3, bubble sensors 300 may be located, positioned and/or arranged to monitor, sense, measure and/or otherwise detect gas bubbles in the plating solution at one or more of the plating cell 110, the overflow pipe or tube 154, the overflow reservoir 156 and/or the recirculation line, pipe or tube 158.

In some suitable embodiments, signals indicative of gas bubble detection or the like from the respective bubble sensors 300 are received and/or obtained by the controller 320. In response thereto, the controller 320 may selectively control, adjust and/or regulate various ECP parameters, for example, to suppress gas bubble formation, nucleation and/or growth. In some suitable embodiments, the controller 320 may selectively control and/or regulate the acoustic wave generators 310 in response to gas bubble detection and/or monitoring. For example, the acoustic wave generators 310, under the control and/or regulation of the controller 320, may selectively generate and/or launch acoustic waves, for example, ultrasonic or megasonic waves, in the plating solution so as to suppress gas bubble formation, nucleation and/or growth within the plating solution. In some suitable embodiments, one or more of the acoustic wave generators 310 may be a piezoelectric transducer or the like which is selectively energized and/or driven to generate and/or launch acoustic waves within the plating solution. Suitably, based at least in part on gas bubble detection and/or monitoring performed by one or more of the bubble sensors 300, the controller 320 may selectively control, adjust and/or regulate the energizing and/or driving of the acoustic wave generators 310 in order to control, adjust and/or regulate the frequency, amplitude and/or other characteristics or parameters of the generated acoustic wave within the plating solution.

In some suitable embodiments, one or more of the respective bubble sensors 300 operate on the principle of capacitive detection and/or employs a capacitive detection technique. In general, capacitive detection detects gas bubbles within the plating solution based upon changes in capacitance corresponding to the permittivity and/or conductivity of the liquid (for example, the plating solution) in the fluidic channel or basin being monitored. In some suitable embodiments, one or more of the respective bubble sensors 300 operate on the principle of photoelectric detection and/or employs a photoelectric detection technique. In general, photoelectric detection detects gas bubble within the plating solution based upon changes in transparency of the plating solution caused by the presence or passing of gas bubbles in front of the bubble sensor 300. In some suitable embodiments, one or more of the respective bubble sensors 300 operate on the principle of ultrasonic detection and/or employs an ultrasonic detection technique. In general, ultrasonic detection detects gas bubbles within the plating solution based upon the ultrasonic transmission and/or attenuation characteristics of the plating solution, for example, such as transmission-medium attenuation, diffusion attenuation, absorptive attenuation, and/or scattering attenuation, or the like which is affected by the presence and/or passing of gas bubbles in front of the bubble sensor 300. In some suitable embodiments, one or more of the bubble sensors 300 may be an imaging sensor that operates on the principle of image processing and/or employs an image processing technique. In general, gas bubble location and/or shape and/or size may be extracted from image data obtained by the sensor 300, for example, using a multi-staged approach of pixel level intensity analysis, for example, by means of computer vision techniques.

In some suitable embodiments, the controller 320 may be implemented via hardware, software, firmware or a combination thereof. In particular, the controller 320 may be embodied by processors, electrical circuits, computers and/or other electronic data processing devices that are configured and/or otherwise provisioned to perform one or more of the tasks, steps, processes, methods and/or functions described herein. For example, a processor, computer, server or other electronic data processing device embodying the controller 320 may be provided, supplied and/or programmed with a suitable listing of code (e.g., such as source code, interpretive code, object code, directly executable code, and so forth) or other like instructions or software or firmware, such that when run and/or executed by the computer or other electronic data processing device one or more of the tasks, steps, processes, methods and/or functions described herein are completed or otherwise performed. Suitably, the listing of code or other like instructions or software or firmware is implemented as and/or recorded, stored, contained or included in and/or on a non-transitory computer and/or machine readable storage medium or media so as to be providable to and/or executable by the computer or other electronic data processing device. For example, suitable storage mediums and/or media can include but are not limited to: floppy disks, flexible disks, hard disks, magnetic tape, or any other magnetic storage medium or media, CD-ROM, DVD, optical disks, or any other optical medium or media, a RAM, a ROM, a PROM, an EPROM, a FLASH-EPROM, or other memory or chip or cartridge, or any other tangible medium or media from which a computer or machine or electronic data processing device can read and use. In essence, as used herein, non-transitory computer-readable and/or machine-readable mediums and/or media comprise all computer-readable and/or machine-readable mediums and/or media except for a transitory, propagating signal. In general, any one or more of the particular tasks, steps, processes, methods, functions, elements and/or components described herein may be implemented on and/or embodiment in one or more general purpose computers, special purpose computer(s), a programmed microprocessor or microcontroller and peripheral integrated circuit elements, an ASIC or other integrated circuit, a digital signal processor, a hardwired electronic or logic circuit such as a discrete element circuit, a programmable logic device such as a PLD, PLA, FPGA, Graphical card CPU (GPU), or PAL, or the like. In general, any device, capable of implementing a finite state machine that is in turn capable of implementing the respective tasks, steps, processes, methods and/or functions described herein can be used.

In the following, some further illustrative embodiments are described.

In some embodiments, a semiconductor electrochemical plating (ECP) tool includes: a plating cell which receives an ECP solution therein; a support onto which a semiconductor substrate is selectively secured, the support being controllable to selectively dip the semiconductor substrate into ECP solution contained in the plating cell; a recirculation system including a reservoir that receives an overflow of ECP solution from the plating cell, the ECP solution being recirculated from the reservoir back to the plating cell; a bubble monitoring system that detects gas bubbles within the ECP solution; and a degassing system that inhibits at least one of gas bubble formation, nucleation and growth within the ECP solution, wherein the degassing system is controlled at least in part based upon gas bubble detection by the bubble monitoring system.

In some further embodiments, the bubble monitoring system includes at least one bubble sensor that detects gas bubble within the ECP solution.

In still additional embodiments, the bubble sensor is positioned to detect gas bubbles within the ECP solution in the plating cell.

In some further embodiments, the bubble sensor is positioned to detect gas bubbles within the ECP solution in the reservoir.

In yet further embodiments, the ECP tool further includes an overflow tube through which the ECP solution flows from the plating cell to the reservoir, wherein the bubble sensor is positioned to detect gas bubbles within the ECP solution in the overflow tube.

In some further embodiments, wherein the ECP tool further includes a recirculation tube through which the ECP solution flows from the reservoir to the plating cell, wherein the bubble sensor is positioned to detect gas bubbles within the ECP solution in the recirculation tube.

In some embodiments, the degassing system includes at least one acoustic wave generator that generates an acoustic wave within the ECP solution to suppress at least one of gas bubble formation, nucleation and growth within the ECP solution.

In yet further embodiments, the at least one acoustic wave generator generates the acoustic wave within at least one of the plating cell and the reservoir.

In some embodiments, the at least one acoustic wave generator includes a piezoelectric transducer that is selectively driven to generate at least one of ultrasonic and megasonic waves.

In still further embodiments, the ECP tool further includes a controller that obtains a signal indicative of gas bubbles detected by the bubble monitoring system and regulates driving of the piezoelectric transducer based at least partially upon the signal.

In yet additional embodiments, the control regulates driving of the piezoelectric transducer to control at least one of an amplitude and frequency of the acoustic wave generated in the ECP solution by the acoustic wave generator.

In some further embodiments, the ECP tool is used to carry out ECP in connection with at least one of a single or a dual damascene process employed for fabrication of a semiconductor device.

In some additional embodiments, a method of electrochemical plating a semiconductor device includes: immersing a semiconductor substrate in a plating solution, the plating solution having an anode therein; producing an electrical potential difference between the semiconductor substrate and the anode; detecting gas bubbles within the plating solution; and at least partially in response to the detecting, selectively generating an acoustic wave within the plating solution to suppress at least one of bubble formation, nucleation and growth.

In some embodiments, the acoustic wave is generated in at least one of a plating cell containing the semiconductor substrate and the anode and a reservoir that supplies the plating solution to the plating cell.

In some embodiments, the detecting detects gas bubbles within the plating solution in at least one of the plating cell, the reservoir, a first pipe carrying an overflow of the plating solution from the plating cell to the reservoir and a second pipe recirculating the plating solution from the reservoir to the plating cell.

In some further embodiments, the acoustic wave is generated by driving a piezoelectric transducer.

In still further embodiments, the acoustic wave is at least one of an ultrasonic wave and a megasonic wave.

In yet further embodiments, an apparatus for electrochemical plating (ECP) a semiconductor device includes: a plating cell arranged to contain a plating solution therein; an anode arranged to be immersed in the plating solution contained in the plating cell; a fixture arranged to hold a semiconductor substrate within the plating solution contained in the plating cell; a power supply arranged to produce an electrical potential differential between the semiconductor substrate and the anode; a reservoir arranged to receive an overflow of plating solution from the plating cell and recirculate the plating solution back to the plating cell; a sensor arranged to detect bubbles within the plating solution; and a wave generator arranged to selectively generate a wave within the plating solution based at least in part upon detection of bubbles by the senor, the wave inhibiting at least one of bubble formation, nucleation and growth within the plating solution.

In still one more embodiment, the apparatus further includes: a first line through which plating solution flows from the plating cell to the reservoir; and a second line through which the plating solution flows from the reservoir to the plating cell; wherein the sensor is arranged to detect bubble within at least one of the plating cell, the reservoir, the first line and the second line.

In yet another embodiment, the wave generator is a piezoelectric transducer that is selectively driven to produce at least one of an ultrasonic wave and a megasonic wave within the plating solution in at least one of the plating cell and the reservoir.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor electrochemical plating (ECP) tool comprising:
a plating cell adapted to receive an ECP solution therein;
a support onto which a semiconductor substrate can be selectively secured, the support being controllable to selectively dip the semiconductor substrate into the ECP solution contained in the plating cell;
a recirculation system including a reservoir adapted to receive an overflow of ECP solution from the plating cell, and able to recirculate the ECP solution from the reservoir back to the plating cell;
a bubble monitoring system adapted to detect gas bubbles within the ECP solution;
and
a degassing system adapted to inhibit at least one of gas bubble formation, nucleation and growth within the ECP solution, wherein the degassing system is controlled at least in part based upon gas bubble detection by the bubble monitoring system.

2. The ECP tool of claim 1, wherein the bubble monitoring system includes:
at least one bubble sensor that detects gas bubbles within the ECP solution.

3. The ECP tool of claim 2, wherein the bubble sensor is positioned to detect gas bubbles within the ECP solution in the plating cell.

4. The ECP tool of claim 2, wherein the bubble sensor is positioned to detect gas bubbles within the ECP solution in the reservoir.

5. The ECP tool of claim 2, further comprising:
an overflow tube through which the ECP solution flows from the plating cell to the reservoir, wherein the bubble sensor is positioned to detect gas bubbles within the ECP solution in the overflow tube.

6. The ECP tool of claim 2, further comprising:
a recirculation tube through which the ECP solution flows from the reservoir to the plating cell, wherein the bubble sensor is positioned to detect gas bubbles within the ECP solution in the recirculation tube.

7. The ECP tool of claim 1, wherein the degassing system includes at least one acoustic wave generator that generates an acoustic wave within the ECP solution to suppress at least one of gas bubble formation, nucleation and growth within the ECP solution.

8. The ECP tool of claim 7, wherein the at least one acoustic wave generator generates the acoustic wave within at least one of the plating cell and the reservoir.

9. The ECP tool of claim 8, wherein the at least one acoustic wave generator includes a piezoelectric transducer that is selectively driven to generate at least one of ultrasonic and megasonic waves.

10. The ECP tool of claim 9, further comprising:
a controller that obtains a signal indicative of gas bubbles detected by the bubble monitoring system and regulates driving of the piezoelectric transducer based at least partially upon the signal.

11. The ECP tool of claim 10, wherein the control regulates driving of the piezoelectric transducer to control at least one of an amplitude and frequency of the acoustic wave generated in the ECP solution by the acoustic wave generator.

12. The ECP tool of claim 1, wherein the ECP tool is used to carry out ECP in connection with at least one of a single or a dual damascene process employed for fabrication of a semiconductor device.

13. A method of electrochemical plating a semiconductor device, the method comprising:
immersing a semiconductor substrate in a plating solution, the plating solution having an anode therein;
producing an electrical potential difference between the semiconductor substrate and the anode;
detecting gas bubbles within the plating solution; and
at least partially in response to the detecting, selectively generating an acoustic wave within the plating solution to suppress at least one of bubble formation, nucleation and growth.

14. The method of claim 13, wherein the acoustic wave is generated in at least one of a plating cell containing the semiconductor substrate and the anode and a reservoir that supplies the plating solution to the plating cell.

15. The method of claim 14, wherein the detecting detects gas bubbles within the plating solution in at least one of the plating cell, the reservoir, a first pipe carrying an overflow of the plating solution from the plating cell to the reservoir and a second pipe recirculating the plating solution from the reservoir to the plating cell.

16. The method of claim 13, wherein the acoustic wave is generated by driving a piezoelectric transducer.

17. The method of claim 13, wherein the acoustic wave is at least one of an ultrasonic wave and a megasonic wave.

18. An apparatus for electrochemical plating (ECP) a semiconductor device, the apparatus comprising:
a plating cell arranged to contain a plating solution therein;
an anode arranged to be immersed in the plating solution contained in the plating cell;
a fixture arranged to hold a semiconductor substrate within the plating solution contained in the plating cell;
a power supply arranged to produce an electrical potential differential between the semiconductor substrate and the anode;
a reservoir arranged to receive an overflow of plating solution from the plating cell and recirculate the plating solution back to the plating cell;
a sensor arranged to detect bubbles within the plating solution; and
a wave generator arranged to selectively generate a wave within the plating solution based at least in part upon detection of bubbles by the senor, the wave inhibiting at least one of bubble formation, nucleation and growth within the plating solution.

19. The apparatus of claim 18, further comprising:
a first line through which plating solution flows from the plating cell to the reservoir; and
a second line through which the plating solution flows from the reservoir to the plating cell;
wherein the sensor is arranged to detect bubble within at least one of the plating cell, the reservoir, the first line and the second line.

20. The apparatus of claim 19, wherein the wave generator is a piezoelectric transducer that is selectively driven to produce at least one of an ultrasonic wave and a megasonic wave within the plating solution in at least one of the plating cell and the reservoir.
